(19) United States
(12) Patent Application Publication
(10) Pub. No.: US 2024/0194527 A1
(43) Pub. Date: Jun. 13, 2024

(54) Interlayer for Resistivity Reduction in Metal Deposition Applications

(71) Applicant: Applied Materials, Inc., Santa Clara, CA (US)

(72) Inventors: Sahil Jaykumar PATEL, Sunnyvale, CA (US); Xianyuan ZHAO, Santa Clara, CA (US); Wei LEI, Campbell, CA (US); Aixi ZHANG, Sunnyvale, CA (US); Yi XU, San Jose, CA (US); Yu LEI, Belmont, CA (US)

(21) Appl. No.: 18/197,846

(22) Filed: May 16, 2023

Related U.S. Application Data
(60) Provisional application No. 63/430,890, filed on Dec. 7, 2022.

(51) Int. Cl. H01L 21/768; H01L 23/532

(52) U.S. Cl. CPC H01L 21/76877; H01L 21/76843; H01L 21/76855; H01L 23/53266

(57) ABSTRACT

Methods and apparatus for processing a substrate are provided. In some embodiments, a method includes depositing an amorphous interlayer atop a first layer on a substrate, wherein the first layer is a metal-containing layer, and depositing a metal layer atop the amorphous interlayer.

### CROSS-REFERENCE TO RELATED APPLICATIONS

This application claims benefit of U.S. provisional patent application Ser. No. 63/430,890, filed Dec. 7, 2022, which is herein incorporated by reference in its entirety.

### FIELD

Embodiments of the present disclosure generally relate to thin film fabrication techniques.

### BACKGROUND

Fabrication of integrated circuits and other microelectronic devices include processes to fill features formed in or on a substrate. Dimensions of the contacts to the source and drain regions, as well as the contact to the metal gate, have drastically decreased over time and continue to decrease. The inventors have observed that contact resistance in semiconductor devices increases dramatically with the reduction in contact and feature dimensions and that conventional methods of filling such features can produce unacceptably high resistance.

The inventors have further observed that depositing low resistivity metals atop certain underlayers can have undesirably increased resistivity in certain applications. For example, titanium nitride (TiN) is often used as a barrier layer between an underlying dielectric layer (such as silicon oxide) and a metal material to be deposited atop the barrier layer. The inventors have observed that depositing tungsten, which is typically a low resistivity metal in bulk that can be used in contact, via, and/or trench applications, shows a significantly higher bulk resistivity when deposited on a titanium nitride (TiN) underlayer.

Accordingly, the inventors have developed improved techniques to deposit a conductive material atop an underlying layer with improved bulk resistivity.

### SUMMARY

Methods and apparatus for processing a substrate are provided. In some embodiments, a method includes depositing an amorphous interlayer atop a first layer on a substrate, wherein the first layer is a metal-containing layer; and depositing a metal layer atop the amorphous interlayer.

In some embodiments, a non-transitory computer readable medium is provided, having instructions stored thereon that, when executed, cause a method to be performed, the method comprising any of the embodiments disclosed herein.

In some embodiments, a system for processing a substrate includes: an amorphous interlayer deposition chamber configured to deposit an amorphous interlayer atop a first layer on a substrate, wherein the first layer is a metal-containing layer; and a metal layer deposition chamber configured to deposit a metal layer atop the amorphous interlayer. In some embodiments, the amorphous interlayer deposition chamber and the metal layer deposition chamber are part of an integrated tool configured to deposit the metal layer atop the amorphous interlayer without breaking vacuum. In some embodiments, such an integrated tool can further include a deposition chamber configured to deposit the first layer atop a dielectric layer of the substrate and within a feature formed in the dielectric layer.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a flow chart of a method of filling a feature on a substrate with a metal in accordance with embodiments of the present disclosure.

FIGS. 2A-2C respectively depict stages of processing of a substrate in accordance with embodiments of the present disclosure.

FIG. 3 depicts a schematic plan view of an integrated tool (e.g., cluster tool) suitable for performing all or some portions of methods in accordance with embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of methods for filling a feature on a substrate with a conductive material are provided herein. Embodiments of the inventive methods include depositing metal on an underlying material using an interlayer that provides a break between the crystalline structure of the underlying material and deposited metal, e.g., to prevent epitaxy and thus advantageously allow deposition of the metal with a larger grain size. The larger grain size of the deposited metal advantageously yields a metal layer having reduced resistivity as compared to depositing the metal directly atop the underling material. Exemplary, but non-limiting applications include metal fill of features such as trenches, vias, or dual damascene structures formed in a dielectric layer. For example, the inventive methods described herein can provide a low resistance liner/fill material in contact vias/trenches, such as where silicide contacts are often capped by titanium nitride or the like.

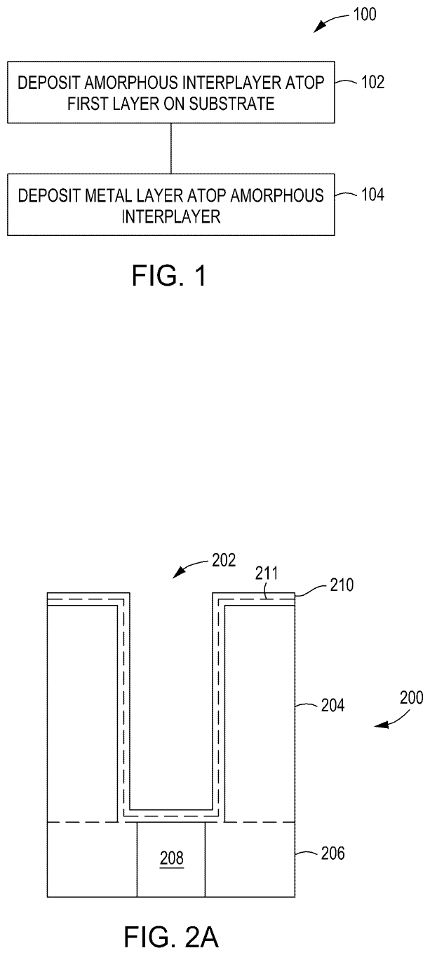

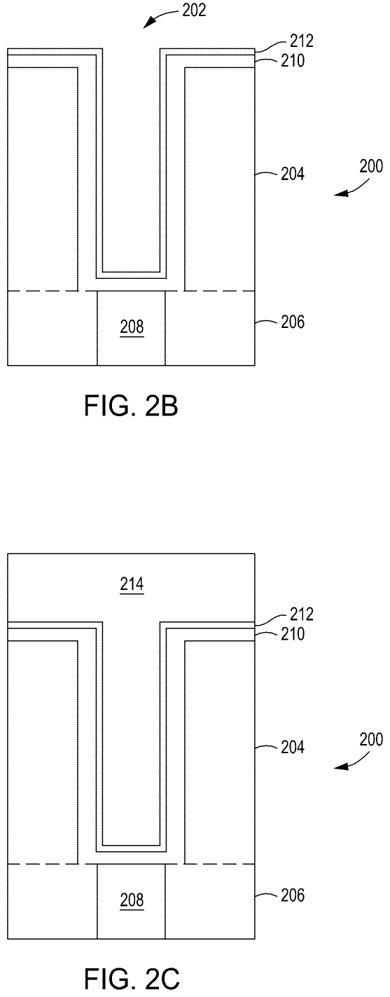

FIG. 1 is a flow chart of a method 100 of filling a feature on a substrate with a metal in accordance with embodiments of the present disclosure. FIGS. 2A-2C respectively depict stages of processing of a substrate in accordance with embodiments of the present disclosure.

The method 100 can be performed on a substrate having a feature formed in or on the substrate. For example, as depicted in FIG. 2A, a substrate 200 includes a feature 202 formed in a dielectric layer 204, such as an interlayer dielectric of an electronic device or structure being fabricated. The feature 202 can be a trench, a via, or a dual damascene structure including one or more trenches and one or more vias. In some embodiments, the feature can be a high aspect ratio (HAR) feature. The feature can have vertical, substantially vertical, or tapered sidewalls. In some embodiments, the feature can have an opening size (e.g., a width) of about 5 nm to about 300 nm.

The dielectric layer 204 can be a silicon oxide layer or other dielectric layer. The substrate 200 can include additional layers such as another dielectric layer 206 disposed beneath the dielectric layer 204. The dielectric layer 206 can be the same material as the dielectric layer 204 or the dielectric layer 206 can be a different material than the dielectric layer 204. A conductive layer 208 can be disposed within the dielectric layers of the substrate, such as within dielectric layer 206 as depicted in FIG. 2A. In some embodiments, the conductive layer 208 can have an upper surface that at least partially defines a bottom of the feature 202. For example, the conductive layer 208 can be a contact pad, a conductive line, a portion of an electronic device such as a transistor, or some other component to which electrical contact is to be made through the feature 202, once filled. The conductive layer 208 can be any conductive material typically used in microelectronic device fabrication.

In some embodiments, a first layer 210 is disposed atop the dielectric layer 204. The first layer 210 can be a metal-containing layer and may function as a barrier layer to prevent damage to the dielectric layer 204 during subsequent processing of the substrate (such as during deposition of additional layers atop the substrate) and/or to limit or prevent undesired interaction between the dielectric layer 204 and any subsequently deposited materials (such as oxidation of subsequently deposited materials or migration of deposited materials into the dielectric layer). In some embodiments, the first layer 210 is a titanium nitride layer. In some embodiments, the titanium nitride layer can be disposed directly atop the dielectric layer. In some embodiments, the titanium nitride layer can be disposed atop a silicide layer, such as a titanium silicide layer (e.g., silicide layer 211 shown in phantom in FIG. 2A), that is disposed atop the dielectric layer. In some embodiments, the first layer 210 is a molybdenum nitride layer. In some embodiments, the molybdenum nitride layer can be disposed directly atop the dielectric layer. In some embodiments, the molybdenum nitride layer can be disposed atop a silicide layer, such as a molybdenum silicide layer (e.g., silicide layer 211 shown in phantom in FIG. 2A), that is disposed atop the dielectric layer.

Other optional layers can include, for example, an etch stop layer or the like used for the fabrication of the feature during prior processing of the substrate 200. The feature 202 can be formed in a conventional manner and, optionally, a preclean process can be provided if needed prior to commencing the method 100.

The method 100 generally begins at block 102, where an amorphous interlayer is deposited atop the first layer 210. For example, as depicted in FIG. 2B, an amorphous interlayer 212 is deposited on the substrate 200, and in particular, atop an upper surface of the substrate 200 (e.g., atop dielectric layer 204) and within the feature 202, including on a bottom of the feature 202 (e.g., atop conductive layer 208) and sidewalls of the feature 202 (e.g., atop dielectric layer 204). The amorphous interlayer can be a conformal layer.

The amorphous interlayer is an amorphous layer of material formed from any application-compatible material (e.g., element or compound) that can be suitably deposited to form a thin amorphous layer. Examples of suitable materials to form the amorphous interlayer include but are not limited to boron, silicon, tungsten silicide, or the like. For example, the amorphous interlayer can consist of or can consist essentially of boron, silicon, tungsten silicide, or the like (e.g., the amorphous interlayer includes primarily the aforementioned materials but may include some impurities incorporated during the deposition process.

The amorphous interlayer is a thin layer of amorphous material at least one atomic layer thick. In some embodiments, the amorphous interlayer is a thin layer of amorphous material having a thickness of at least 2 angstroms. In some embodiments, the amorphous interlayer is an insulating or non-metallic layer having a thickness of between one atomic layer and about 10 angstroms, or between about 2-10 angstroms. In some embodiments, the amorphous interlayer is a conductive layer having a thickness of between one atomic layer and about 5 nanometers, or about 2 angstroms to about 5 nanometers.

The amorphous interlayer can be deposited using a suitable process depending upon the material to be deposited. For example, if the amorphous interlayer is a boron layer, the layer can be illustratively deposited by a B₂H₆ soak at >300 degrees Celsius. For example, if the amorphous interlayer is a silicon layer, the layer can be illustratively deposited by a plasma enhanced atomic layer deposition (PEALD) process using a silane (SiH₄) precursor and an H₂ and/or Ar plasma. For example, if the amorphous interlayer is a tungsten silicide layer, the layer can be illustratively deposited by a chemical vapor deposition (CVD) process using tungsten hexafluoride (WF₆) and silane (SiH₄). In some embodiments, a physical vapor deposition process can alternatively be used.

Next, at block 104, a metal layer is deposited on the amorphous interlayer. For example, as depicted in FIG. 2C, a metal layer 214 can be deposited on the substrate 200, and in particular, atop the upper surface of the substrate and within the feature 202 (e.g., atop the amorphous interlayer 212).

Examples of suitable metals to form the metal layer include but are not limited to tungsten or the like. For example, the metal layer can consist of or can consist essentially of tungsten or the like. Other metals typically used in microelectronic device fabrication can also be used, for example, cobalt, copper, molybdenum, ruthenium, tantalum, titanium, or the like.

The metal layer can be deposited using a CVD or PVD process. One example of a suitable process for depositing a metal layer is described in U.S. patent Ser. No. 17/977,411, filed Oct. 31, 2022, by Sahil Patel, et al., and entitled “Buffer Layer for Dielectric Protection in Physical Vapor Deposition Metal Liner Applications.”

For example, using the teachings provided herein, an amorphous interlayer (e.g., amorphous interlayer 212) can be provided in a patterned structure (e.g., feature 202) such that the epitaxial growth effects of an underlying layer (such as a titanium nitride layer, e.g., the first layer 210) on a metal (such as tungsten, e.g., the metal layer 214) are advantageously blocked. The blocking of the epitaxial growth effects advantageously allows the metal layer (e.g., tungsten) to form larger grains, which significantly reduces the resistivity of the metal layer. In some embodiments, the metal layer is deposited using both PVD and CVD, with PVD tungsten deposition serving as a template for subsequent bulk CVD tungsten fill. In such embodiments, the resulting CVD tungsten material also has a low resistivity due to the underlying low resistivity PVD tungsten film deposited atop the amorphous layer. In certain applications, such as deposition of tungsten atop a titanium nitride barrier layer (e.g., a titanium nitride first layer), the inventors have observed an up to 40% reduction in resistivity by using the methods as described herein. The bulk resistivity improvement of 40% can advantageously contribute significantly to reduction in contact resistance (Rc). Although described with respect to FIG. 2 as filling a feature, the inventive methods can also be used for blanket deposition applications.

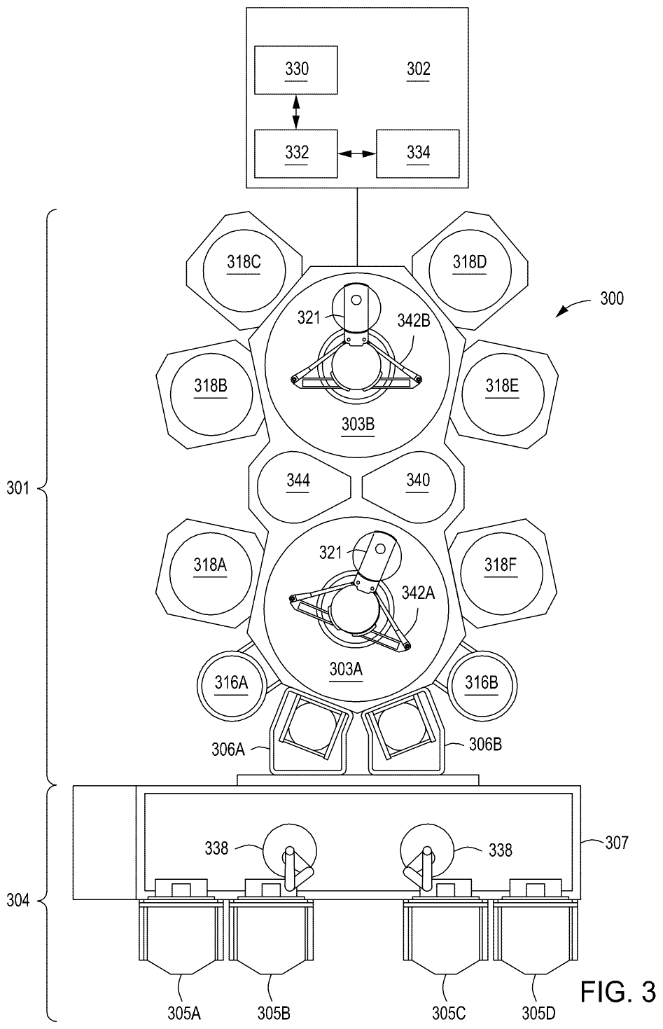

In some embodiments, the metal layer deposition chamber can be part of an integrated tool containing another chamber configured to deposit the amorphous interlayer (e.g., an amorphous interlayer deposition chamber). For example, the methods as described above may be performed in standalone processing chambers or at least in part in a cluster tool, for example, the integrated tool 300 (e.g., cluster tool) described below with respect to FIG. 3. The advantage of using an integrated tool 300 is that there is no vacuum break between chambers and, therefore, no requirement to degas and pre-clean a substrate before further processing.

For example, in some embodiments, a sequence of processes include depositing a first layer (such as a titanium nitride barrier layer) atop a dielectric layer and along a feature formed in the dielectric layer of the substrate (such as a silicon oxide layer), depositing an amorphous interlayer atop the first layer, and depositing a metal layer atop the amorphous interlayer to fill the feature. In such a sequence, all processes can be performed in a single integrated platform without vacuum break. Alternatively, a vacuum break can be provided after the first layer is deposited, for example to switch from a tool that is used to deposit the first layer to a different tool used to deposit the amorphous interlayer and subsequent metal layer. Alternatively, a vacuum break can be provided after the amorphous interlayer is deposited, for example to switch from a tool that is used to deposit the amorphous interlayer to a different tool used to deposit the metal layer.

For example, in some embodiments, a sequence of processes include forming a feature in the dielectric layer of the substrate (such as a silicon oxide layer), depositing a first layer (such as a titanium nitride barrier layer) atop the dielectric layer and along the feature, depositing an amorphous interlayer atop the first layer, and depositing a metal layer atop the amorphous interlayer to fill the feature. In such a sequence, all processes can be performed in a single integrated platform without vacuum break. Alternatively, a vacuum break can be provided after the first layer is deposited, for example to switch from a tool that is used to deposit the first layer to a different tool used to deposit the amorphous interlayer and subsequent metal layer. Alternatively, a vacuum break can be provided after the amorphous interlayer is deposited, for example to switch from a tool that is used to deposit the amorphous interlayer to a different tool used to deposit the metal layer.

For example, in some embodiments the inventive methods discussed above may advantageously be performed in an integrated tool such that there are limited or no vacuum breaks between processes, limiting or preventing contamination of the substrate such as by oxidation or the like. The integrated tool 300 includes a vacuum-tight processing platform 301, a factory interface 304, and a system controller 302. The processing platform 301 comprises multiple process chambers, such as 318A, 318B, 318C, 318D, 318E, and 318F operatively coupled to a vacuum substrate transfer chamber (transfer chambers 303A, 303B. The factory interface 304 is operatively coupled to the transfer chamber 303A by one or more load lock chambers (two load lock chambers, such as 306A and 306B shown in FIG. 3).

In some embodiments, the factory interface 304 comprises at least one docking station 307 and at least one factory interface robot 338 to facilitate the transfer of the semiconductor substrates. The docking station 307 is configured to accept one or more front opening unified pods (FOUP). Four FOUPS, such as 305A, 305B, 305C, and 305D are shown in the embodiment of FIG. 3. The factory interface robot 338 is configured to transfer the substrates from the factory interface 304 to the processing platform 301 through the load lock chambers, such as 306A and 306B. Each of the load lock chambers 306A and 306B have a first port coupled to the factory interface 304 and a second port coupled to the transfer chamber 303A. The load lock chamber 306A and 306B are coupled to a pressure control system (not shown) which pumps down and vents the load lock chambers 306A and 306B to facilitate passing the substrates between the vacuum environment of the transfer chamber 303A and the substantially ambient (e.g., atmospheric) environment of the factory interface 304. The transfer chambers 303A, 303B have vacuum robots 342A, 342B disposed in the respective transfer chambers 303A, 303B. The vacuum robot 342A is capable of transferring substrates 321 (e.g., the substrate 200 during performance of the method 100) between the load lock chamber 306A, 306B, the process chambers 318A and 318F and a cooldown station 340 or a pre-clean station 344. The vacuum robot 342B is capable of transferring substrates 321 between the cooldown station 340 or pre-clean station 344 and the process chambers 318B, 318C, 318D, and 318E.

In some embodiments, the process chambers 318A, 318B, 318C, 318D, 318E, and 318F are coupled to the transfer chambers 303A, 303B. The process chambers 318A, 318B, 318C, 318D, 318E, and 318F may comprise, for example, substrate soaking chambers, atomic layer deposition (ALD) process chambers, physical vapor deposition (PVD) process chambers, remote plasma chambers, chemical vapor deposition (CVD) chambers, annealing chambers, or the like. The chambers may include any chambers suitable to perform all or portions of the methods described herein, as discussed above, such as one or more CVD and/or PVD chambers configured to deposit the amorphous interlayer and the metal layer, and the like. In some embodiments, one or more optional service chambers (shown as 316A and 316B) may be coupled to the transfer chamber 303A. The service chambers 316A and 316B may be configured to perform other substrate processes, such as degassing, orientation, substrate metrology, cool down, and the like.

The system controller 302 controls the operation of the tool 300 using a direct control of the process chambers 318A, 318B, 318C, 318D, 318E, and 318F or alternatively, by controlling the computers (or controllers) associated with the process chambers 318A, 318B, 318C, 318D, 318E, and 318F and the tool 300. In operation, the system controller 302 enables data collection and feedback from the respective chambers and systems to optimize performance of the tool 300. The system controller 302 generally includes a central processing unit (CPU) 330, a memory 334, and a support circuit 332.

The CPU 330 may be any form of a general-purpose computer processor that can be used in an industrial setting. The support circuit 332 is conventionally coupled to the CPU 330 and may comprise a cache, clock circuits, input/output subsystems, power supplies, and the like. Software routines, such as methods as described herein may be stored in the memory 334 and, when executed by the CPU 330, transform the CPU 330 into a specific purpose computer (system controller 302). The software routines may also be stored and/or executed by a second controller (not shown) that is located remotely from the tool 300.

The memory 334 is in the form of computer-readable storage media that contains instructions, when executed by the CPU 330, to facilitate the operation of the semiconductor processes and equipment. The instructions in the memory 334 are in the form of a program product such as a program that implements the methods of the present principles. The program code may conform to any one of a number of different programming languages. In one example, the disclosure may be implemented as a program product stored on a computer-readable storage media for use with a computer system. The program(s) of the program product define functions of the aspects (including the methods described herein). Illustrative computer-readable storage media include, but are not limited to: non-writable storage media (e.g., read-only memory devices within a computer such as CD-ROM disks readable by a CD-ROM drive, flash memory, ROM chips, or any type of solid-state non-volatile semiconductor memory) on which information is permanently stored; and writable storage media (e.g., floppy disks within a diskette drive or hard-disk drive or any type of solid-state random access semiconductor memory) on which alterable information is stored. Such computer-readable storage media, when carrying computer-readable instructions that direct the functions of the methods described herein, are aspects of the present principles.

While the foregoing is directed to embodiments of the present disclosure, other and further embodiments of the disclosure may be devised without departing from the basic scope thereof.

1. A method for processing a substrate, comprising:
depositing an amorphous interlayer atop a first layer on a substrate, wherein the first layer is a metal-containing layer; and
depositing a metal layer atop the amorphous interlayer.

2. The method of claim 1, wherein the first layer is a barrier layer deposited within a feature formed at least partially in a dielectric layer on the substrate.

3. The method of claim 1, wherein the amorphous interlayer is a boron, silicon, or tungsten silicide layer.

4. The method of claim 1, wherein the substrate includes a feature formed in the first layer and the amorphous interlayer is deposited atop the first layer and along sidewalls and a bottom the feature.

5. The method of claim 1, wherein the first layer is a titanium nitride layer.

6. The method of claim 5, wherein the amorphous interlayer is a boron, silicon, or tungsten silicide layer.

7. The method of claim 1, wherein the amorphous interlayer is deposited to a thickness of one atomic layer to about 5 nanometers.

8. The method of claim 1, wherein the amorphous interlayer is deposited to a thickness of one atomic layer to about 10 angstroms.

9. The method of claim 1, wherein the amorphous interlayer and the metal layer are deposited sequentially without vacuum break.

10. A non-transitory computer readable medium, having instructions stored thereon that, when executed, cause a method for processing a substrate to be performed, the method comprising:
depositing an amorphous interlayer atop a first layer on a substrate, wherein the first layer is a metal-containing layer; and
depositing a metal layer atop the amorphous interlayer.

11. The non-transitory computer readable medium of claim 10, wherein the amorphous interlayer is a boron, silicon, or tungsten silicide layer.

12. The non-transitory computer readable medium of claim 10, wherein the substrate includes a feature formed in the first layer and the amorphous interlayer is deposited atop the first layer and along sidewalls and a bottom the feature.

13. The non-transitory computer readable medium of claim 10, wherein the first layer is a titanium nitride layer.

14. The non-transitory computer readable medium of claim 13, wherein the amorphous interlayer is a boron, silicon, or tungsten silicide layer.

15. The non-transitory computer readable medium of claim 10, wherein the amorphous interlayer is deposited to a thickness of one atomic layer to about 5 nanometers.

16. The non-transitory computer readable medium of claim 10, wherein the amorphous interlayer is deposited to a thickness of one atomic layer to about 10 angstroms.

17. The non-transitory computer readable medium of claim 10, wherein the amorphous interlayer and the metal layer are deposited sequentially without vacuum break.

18. A system for processing a substrate, comprising:
an amorphous interlayer deposition chamber configured to deposit an amorphous interlayer atop a first layer on a substrate, wherein the first layer is a metal-containing layer; and
a metal layer deposition chamber configured to deposit a metal layer atop the amorphous interlayer.

19. The system of claim 18, wherein the amorphous interlayer deposition chamber and the metal layer deposition chamber are part of an integrated tool configured to deposit the metal layer atop the amorphous interlayer without breaking vacuum.

20. The system of claim 18, further comprising:
a deposition chamber configured to deposit the first layer atop a dielectric layer of the substrate and within a feature formed in the dielectric layer.
